(19) United States
(12) Patent Application Publication
(10) Pub. No.: US 2025/0283766 A1
(43) Pub. Date: Sep. 11, 2025

(54) RESISTIVE SENSOR CIRCUIT

(71) Applicant: APPLE INC., CUPERTINO, CA (US)

(72) Inventors: CRAIG P. FINLINSON, CARLSBAD, CA (US); KE YUN, CUPERTINO, CA (US); BRUNO W. GARLEPP, SUNNYVALE, CA (US); GIN S. YEE, MOUNTAIN VIEW, CA (US)

(21) Appl. No.: 19/056,058

(22) Filed: Feb. 18, 2025

Related U.S. Application Data
(60) Provisional application No. 63/563,836, filed on Mar. 11, 2024.

(51) Int. Cl. G01K 7/24; H01C 7/06; H01C 13/02; H01L 23/522

(52) U.S. Cl. CPC G01K 7/24; H01C 13/02; H01C 7/06; H01L 23/5228

(57) ABSTRACT

An apparatus is provided. The apparatus includes a first resistor stack having a first temperature coefficient. The apparatus also includes a second resistor stack coupled to the first resistor stack having a second temperature coefficient different than the first temperature coefficient. The apparatus further includes a measurement circuit associated configured to determine a temperature of the apparatus based on a differential between a first voltage across the first resistor stack and a second voltage across the second resistor stack and determine a set of resistances of a field-effect transistor (FET) that is coupled to the apparatus based on additional differentials between additional voltages across the first resistor stack and the second resistor stack.

### CROSS-REFERENCE TO RELATED APPLICATION

This application is a non-provisional application for patent entitled to a filing date and claiming the benefit of earlier-filed U.S. Provisional Patent Application No. 63/563,836, filed Mar. 11, 2024, which is hereby incorporated herein by reference in its entirety.

### BACKGROUND

### Technical Field

Embodiments described herein relate to temperature sensors for electronic circuits. More particularly, embodiments described herein relate to resistive sensor structures and resistive sensor circuits.

### Description of the Related Art

As features sizes have decreased, the number of transistors on integrated circuits (ICs) has correspondingly increased. The increased number of transistors per unit area has resulted in a corresponding increase in power per unit area and, accordingly, thermal output (heat generation) of ICs. This trend has occurred despite the fact that the increased number of transistors per unit area has also corresponded to a decrease in the supply voltages provided to various functional circuitry on an IC. These trends have in turn led to significant challenges in balancing performance, power consumption, and thermal output of ICs. To this end, many ICs implement subsystems that monitor various metrics of the IC (e.g., temperature, voltage, voltage drops) and adjust the performance of the IC based on received measurements from these subsystems. Temperature is one metric that is commonly monitored for various reasons. Resistance of different circuits and/or devices is also monitored for various reasons. Accordingly, an IC may have temperature and/or resistance sensors implemented thereon (e.g., within certain functional circuit blocks). Such temperature/resistance sensors may provide temperature/resistance readings to other circuits that carry out various control functions, such as adjusting voltages, clock frequencies, and/or workloads of various functional circuit blocks based on their respectively reported temperatures.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a cross-sectional representation of an embodiment of a resistor structure.

FIG. 2 depicts a top-view representation of an embodiment of a horizontal pitch layer of a metal trace.

FIG. 3 depicts a top-view representation of an embodiment of a vertical pitch layer of a metal trace.

FIG. 4 depicts a top-view representation of an embodiment of a two-layer resistor unit.

FIG. 5 depicts a top view-representation of an embodiment of a resistor unit.

FIG. 6 depicts a block diagram of an embodiment of a sensor circuit, according to some embodiments.

FIG. 7 depicts a block diagram of an embodiment of a sensor circuit, according to some embodiments.

FIG. 8 is a flow diagram illustrating a method for determining a temperature and one or more resistances of a device, according to some embodiments.

FIG. 9 is a flow diagram illustrating a method for determining a temperature and one or more resistances of a device, according to some embodiments.

FIG. 10 depicts a block diagram of an embodiment of a sensor node, according to some embodiments.

FIG. 11 is a flow diagram illustrating a method for calibrating a sensor, according to some embodiments.

FIG. 12 depicts a block diagram of an embodiment of an integrated circuit (IC).

FIG. 13 is a block diagram of one embodiment of an example system, according to some embodiments.

In the following description, numerous specific details are set forth to provide a thorough understanding of the disclosed embodiments. One having ordinary skill in the art, however, should recognize that aspects of disclosed embodiments might be practiced without these specific details. In some instances, well-known circuits, structures, signals, computer program instruction, and techniques have not been shown in detail to avoid obscuring the disclosed embodiments.

### DETAILED DESCRIPTION OF EMBODIMENTS

The present disclosure is directed to resistive temperature sensors usable in integrated circuits. As feature sizes of devices on integrated circuits have become smaller, the density of circuitry has correspondingly increased. Increased density of circuitry can result in higher density power consumption, and thus, faster temperature rises in “hotspots” (e.g., high activity portions of the IC) occurring during operation of an integrated circuit. Furthermore, these hotspots may be more localized due to the increased circuit density. In addition, the resistance of a circuit at different temperatures may change. Thus, implementing sensing circuitry (e.g., temperature/resistance sensors) within these high-density circuits has become more challenging.

For instance, hotspot sensors may be needed in SoCs (systems-on-chips) to maximize the peak performance capabilities of CPU and graphics cores in small geometries where the power density can be extremely high for short durations. Bipolar-based temperature sensors are often used but are subject to performance changes and degradations from the foundry as they are optimized for MOS performance. These issues lead to unpredictable accuracy and late changes in bipolar-based temperature sensors, which may lead to product risk, chum, and potentially compromised performance.

The present disclosure is directed to temperature/resistance sensors that utilize simple resistors and rely on the resistors' temperature sensitivity to provide temperature sensing. The temperature sensitive resistors may be well defined and have less structural complexities, which can lead to spread in temperature sensing. The present disclosure is also directed to a temperature/resistance sensor circuit implementing the temperature sensitive resistors. The temperature/resistance sensor circuit implements the temperature sensitive resistors along with the resistors that are relatively stable with temperature to output a signal with a voltage that is indicative of the temperature sensed by the circuit. Other embodiments can utilize any two resistors with differing temperature coefficients, positive or negative, depending on available technology and desired temperature characteristic. In some embodiments, the signal from the temperature sensitive resistors is increased through the use of a feedback resistor loop where the feedback resistor may have the same temperature sensitivity as the temperature sensitive resistors.

In various embodiments, one or both of these two types of resistors can be formed through utilization of the metal interconnect stack in a given technology. Additionally, other embodiments are possible where one or both of the resistors are provided through the foundry technology resistor layers, if available. In certain embodiments, a first stack forms a resistor with a high positive temperature coefficient to provide the temperature sensitive resistor and a second stack (typically above the first stack) forms a resistor that has a suitably different temperature coefficient (negative or positive). The combination of these two stacks provides a structure for extracting a strong temperature signal. Various embodiments of resistor stacks and temperature/resistance sensor circuits implementing such resistor stacks are now discussed in further detail.

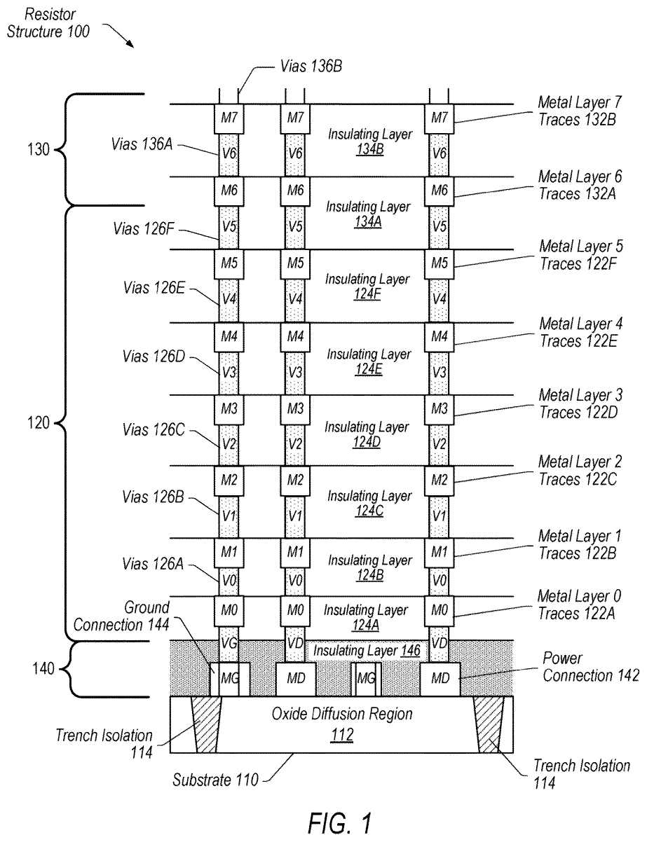

FIG. 1 depicts a cross-sectional representation of an embodiment of a resistor structure. In the illustrated embodiment, resistor structure 100 includes substrate 110 with first resistor stack 120 and second resistor stack 130 formed on the substrate. In certain embodiments, substrate 110 is a silicon substrate. In various embodiments, substrate 110 includes an oxide diffusion region 112 between trench isolations 114.

First resistor stack 120 may include a number of metal and electrically insulating layers (“insulating layers”) with structures (e.g., traces) in the metal layers connected by vias through the insulating layers. For instance, in the illustrated embodiment, first resistor stack 120 includes six metal layers (e.g., “metal layer 0” through “metal layer 5”) and six insulating layers (e.g., insulating layers 124A-124F). It should be understood that any number of metal layers and insulating layers may be implemented depending on, for example, resistance requirements or other operating requirements for the resistor stack. Insulating layers 124A-124F encapsulate (e.g., surround) the respective metal structures in each metal layer (e.g., metal traces 122A-122F for metal layers 0-5) providing electrical insulation and electrically separating the metal traces. Metal traces for each metal layer are also designated by “M0” (metal layer 0 traces 122A), “M1” (metal layer 1 traces 122B), “M2” (metal layer 2 traces 122C), “M3” (metal layer 3 traces 122D), “M4” (metal layer 4 traces 122E), and “M5” (metal layer 5 traces 122F) in first resistor stack 120, as shown in FIG. 1.

In the illustrated embodiment, vias at each level in first resistor stack 120 are designated by “V0” (vias 126A), “V1” (vias 126B), “V2” (vias 126C), “V3” (vias 126D), “V4” (vias 126E), and “V5” (vias 126F). Vias (e.g., vias 126A-126F) may connect metal traces 122 in a metal layer to metal traces 122 in another metal layer through the insulating layers 124. For instance, vias 126A may connect metal layer 0 traces 122A (M0) to metal layer 1 traces 122B (M1), vias 126B may connect metal layer 1 traces 122B (M1) to metal layer 2 traces 122C (M2), etc.

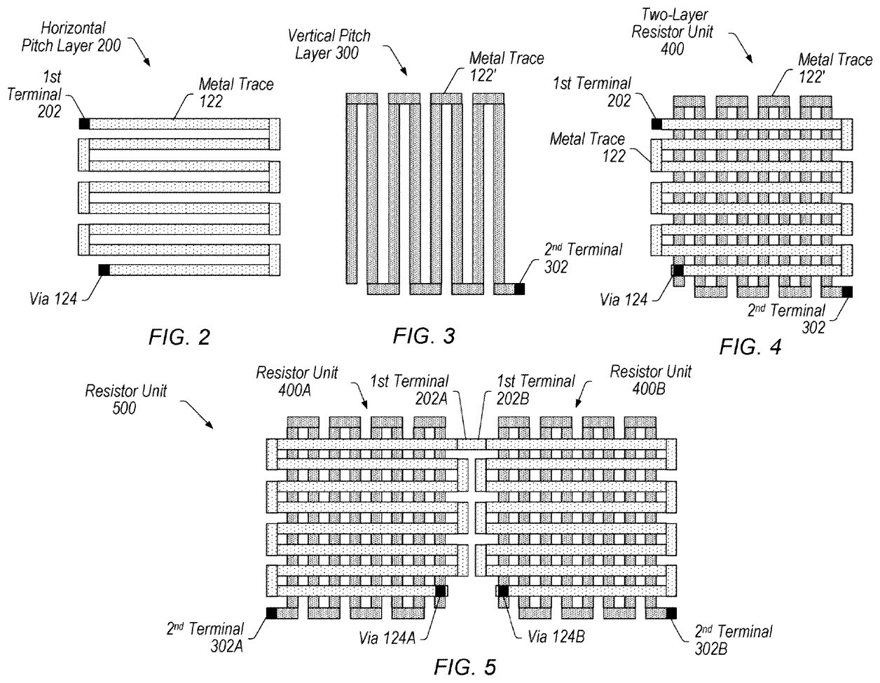

In some embodiments, the pitch of metal traces 122 in first resistor stack 120 are alternated (e.g., between horizontal and vertical). FIG. 2 depicts a top-view representation of an embodiment of a horizontal pitch layer 200 of metal trace 122. FIG. 3 depicts a top-view representation of an embodiment of a vertical pitch layer 300 of metal trace 122′. The metal traces 122/122′ in horizontal pitch layer 200 and vertical pitch layer 300, respectively, may be overlapped and connected to form a two-layer resistor unit.

FIG. 4 depicts a top-view representation of an embodiment of two-layer resistor unit 400. In various embodiments, metal trace 122 includes a first terminal 202 at one end and via 124 at a second end while metal trace 122′ includes a second terminal 302 (also shown in FIGS. 2 and 3). First terminal 202 and second terminal 302 may be end terminals for two-layer resistor unit 400 with via 124 providing an intermediate connection between metal trace 122 and metal trace 122′ between the end terminals. Accordingly, metal trace 122 and metal trace 122′ may be coupled in series between first terminal 202 and second terminal 302 by via 124. While FIGS. 2-4 depict possible patterns for metal traces 122 in first resistor stack 120, it should be understood that additional embodiments with other designs of metal traces may be implemented to provide similar properties to the disclosed embodiments of first resistor stack 120.

In some contemplated embodiments, another resistor unit may be built out of two (two-layer) resistor units 400 coupled in series through first terminal 202. FIG. 5 depicts a top view-representation of an embodiment of resistor unit 500. Resistor unit 500 includes two resistor units 400A, 400B coupled side-by-side in series at first terminals 202A, 202B (e.g., each resistor unit's respective first terminal). Coupling resistor units 400A, 400B side-by-side, as shown in FIG. 5, allows connectivity to resistor unit 500 in the same metal layer. For instance, both first terminal 202A for first resistor unit 400A and first terminal 202B for second resistor unit 400B are positioned in a first metal layer while both second terminal 302A for first resistor unit 400A and second terminal 302B for second resistor unit 400B are positioned in a second metal layer.

Turning back to FIG. 1, second resistor stack 130 is formed above (e.g., on top of) first resistor stack 120. In certain embodiments, second resistor stack 130 includes metal layers having metal traces 132 and insulating layers 134. In one contemplated embodiment, second resistor stack include layers of metal traces (metal layer 6 traces 132A and metal layer 7 traces 132B, which are also designated as “M6” and “M7”, respectively). These metal traces 132 may be connected by vias 136 through insulating layers 134. For instance, vias 136A (“V6”) may connect metal layer 6 traces 132A to metal layer 7 traces 132B through insulating layer 134B.

In some embodiments, as shown in FIG. 1, metal layer 6 traces 132A are coupled to metal 5 layer traces 122F in first resistor stack 120. For example, vias 126F (“V5”) may connect metal layer 6 traces 132A to metal 5 layer traces 122F. In some embodiments, metal layer 6 traces 132A are connected to metal 5 layer traces 122F to connect the resistor in second resistor stack 130 in series to the resistor in first resistor stack 120, as described herein. It is possible, however, that some of metal layer 6 traces 132A may be connected to some of metal 5 layer traces 122F that do not form a part of the resistor in first resistor stack 120. Vias 136B may connect metal layer 7 traces 132B to any additional metal traces or devices positioned above second resistor stack 130. For instance, vias 136B may connect metal layer 7 traces 132B to metal layer 8 traces that provide connections to various circuit components described herein.

In various embodiments, power routing layer 140 is formed between substrate 110 and first resistor stack 120. Power routing layer 140 may be formed to provide power and ground connections to first resistor stack 120. For example, power routing layer 140 may be a metal layer and an insulating layer with vias connecting the metal layer to first resistor stack 120 through the insulating layer. In the illustrated embodiment, power routing layer 140 includes power connections 142 (“MD” and “VD”) and ground connections 144 (“MG” and “VG”) to first resistor stack 120 with insulating layer 146 surrounding the power and ground connections. Power routing layer 140 may further include routings (not shown) to various power and ground sources on substrate 110.

In various embodiments, one or more resistors are formed from first resistor stack 120 and second resistor stack 130 on substrate 110. These resistors may have specific resistive properties determined by the materials and design of the respective resistor stacks. For example, in one contemplated embodiment, first resistor stack 120 forms a first resistor with a first set of specific resistive properties and second resistor stack 130 forms a second resistor with a second set of specific resistive properties. Additional embodiments may be contemplated where first resistor stack 120 or second resistor stack 130 form multiple resistors where each resistor formed in a resistor stack has similar resistive properties.

First resistor stack 120 and second resistor stack 130 may form resistors with specific resistive properties for implementation in temperature sensor circuits such as those described herein. For instance, in certain embodiments, first resistor stack 120 forms a resistor that has a positive temperature coefficient while second resistor stack 130 forms a resistor that has a negative temperature coefficient. First resistor stack 120 may have the positive temperature coefficient while second resistor stack 130 has the negative temperature coefficient to provide differential temperature properties between the first resistor stack and the second resistor stack. In some embodiments, second resistor stack 130 may form a resistor that has a positive temperature coefficient (e.g., a positive temperature coefficient less than the temperature coefficient of first resistor stack 120). In such embodiments, the positive temperature coefficient of first resistor stack 120 is sufficiently higher than the positive temperature coefficient of second resistor stack 130, as described below, to provide differential temperature properties between the first resistor stack and the second resistor stack.

These differential temperature properties may allow first resistor stack 120 and second resistor stack 130 to be implemented as resistors for temperature sensor circuits described herein. For example, first resistor stack 120 and second resistor stack 130 may be placed in circuits that output a signal with a voltage that corresponds to a differential between a first voltage across the first resistor stack and a first voltage across the second resistor stack. The voltage of the signal changes based on temperature due to the differential temperature properties of first resistor stack 120 and second resistor stack 130 and thus, a temperature may be determined based on the voltage of the signal.

In certain embodiments, the temperature coefficient for first resistor stack 120 has a higher magnitude than the temperature coefficient for second resistor stack 130 (e.g., the positive temperature coefficient of the first resistor stack has a larger absolute value than the negative (or positive) temperature coefficient of the second resistor stack). For example, the absolute value of the temperature coefficient of first resistor stack 120 may be at least two times the absolute value of the temperature coefficient of second resistor stack 130. In certain embodiments, the absolute value of the temperature coefficient of first resistor stack 120 may be at least five times the absolute value of the temperature coefficient of second resistor stack 130.

In various embodiments, first resistor stack 120 may have a positive temperature coefficient with an absolute value of at least about 500 ppm/° C. (e.g., the positive temperature coefficient is greater than about 500 ppm/° C.) while second resistor stack 130 has a negative (or positive) temperature coefficient with an absolute value of at most about 200 ppm/° C. (e.g., the temperature coefficient is between 0 ppm/° C. and about −200 ppm/° C. or between 0 ppm/° C. and about 200 ppm/° C.). Accordingly, the resistance of first resistor stack 120 is more sensitive to temperature than the resistance of second resistor stack 130. In some embodiments, the resistance of second resistor stack 130 is relatively stable with temperature (e.g., the negative or positive temperature coefficient is close to zero). Additionally, in various embodiments, the resistance of second resistor stack 130 is relatively high (e.g., the second resistor stack is a Hi-R resistor).

In one contemplated embodiment, first resistor stack 120 has a temperature coefficient of +700 ppm/° C. while second resistor stack has a temperature coefficient of −130 ppm/° C. In such an embodiment, first resistor stack 120 is 11.5× more sensitive to temperature than second resistor stack 130. The higher sensitivity of first resistor stack 120 may enable temperature measurement based on differentials in resistance changes between the first resistor stack and second resistor stack 130.

In various embodiments, the metal layers (e.g., metal traces) in first resistor stack 120 also have improved piezoresistivity compared to doped silicon. For instance, the metal layers in first resistor stack 120 may have a piezoresistivity that is about 2 orders of magnitude less than a piezoresistivity of doped silicon. In some embodiments, the metal layers in second resistor stack 130 may also have a lower piezoresistivity than doped silicon. The lower piezoresistivity may reduce the effects of packaging or mechanical stress on the resistance of first resistor stack 120. Thus, temperature sensing using circuits with first resistor stack 120 and second resistor stack 130 may be less sensitive to mechanical variations caused during manufacturing. Additionally, first resistor stack 120 and second resistor stack 130 may be placed under bumps or other connections that cause additional mechanical stress without affecting the temperature sensing properties of the resistor stacks.

In certain embodiments, first resistor stack 120 has an electrical resistivity between 10Ω/μm and 30Ω/μm. For instance, first resistor stack 120 may have an electrical resistivity of about 20Ω/μm. Such electrical resistivities may provide reasonable resistances for generating voltage drops that can be sensed/detected by the temperature sensing circuits described herein. Additionally, such electrical resistivities may allow low voltage operation.

Various sensor circuits that are based on resistor stacks with different temperature coefficients are described herein. For example, sensor circuits 600, 700 may implement different temperature coefficient resistors based on first resistor stack 120 and second resistor stack 130. The various sensor circuits described herein may be implemented at a reduced chip area cost relative to other known sensor circuits. For example, sensor circuits based on first resistor stack 120 and second resistor stack 130 may have a reduced chip area cost relative to bipolar junction-based sensors and μ-bipolar junction-based sensors.

The sensor circuits based on first resistor stack 120 and second resistor stack 130 that are described herein may also have similar, or even better, temperature sensing accuracy to implementations of bipolar junction-based sensors and μ-bipolar junction-based sensors. For instance, the sensor circuits disclosed herein may have a 3σ sensor accuracy of less than about ±3° C. The disclosed sensor circuits may also have reduced power consumption compared to bipolar junction-based sensors and μ-bipolar junction-based sensors. For instance, the disclosed sensor circuits may have power consumption that is two orders of magnitude or greater below the power consumption of bipolar junction-based sensors and μ-bipolar junction-based sensors. The sensor circuits disclosed herein have the capability to run from lower supply voltages than bipolar junction-based counterparts. They also possess better inherent power supply noise rejection through the global closed loop concept and ratiometric power supply derived signal and reference currents. The sensor circuits disclosed herein may permit SoC's to use a lower cost process technology by utilizing existing metal interconnect stack as a resistive transducer. The sensor circuits disclosed herein may allow reduced sensitivity to mechanical stress and strain compared to bipolar junction-based sensors.

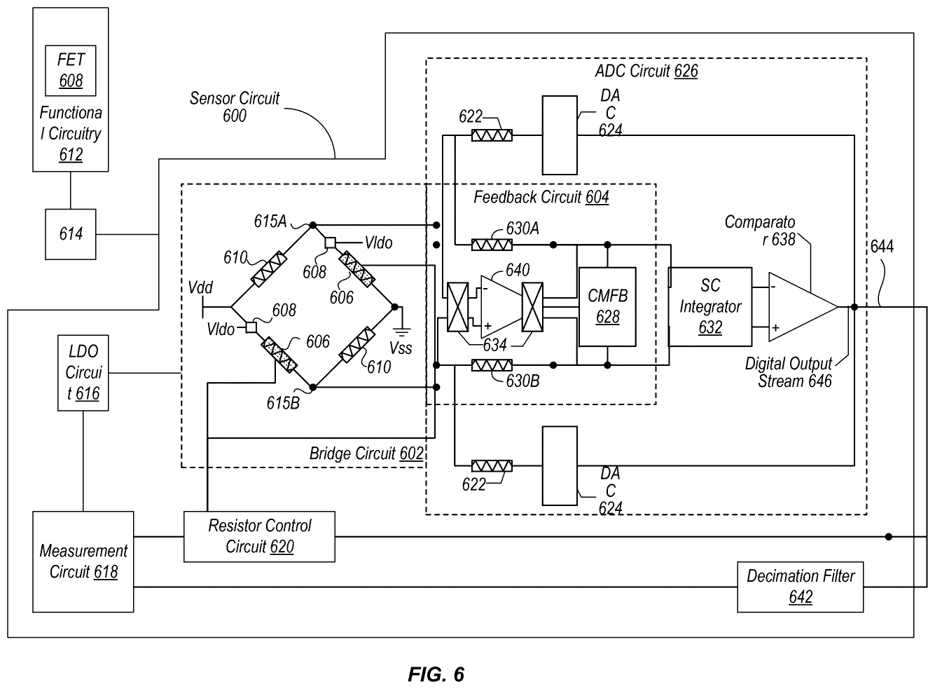

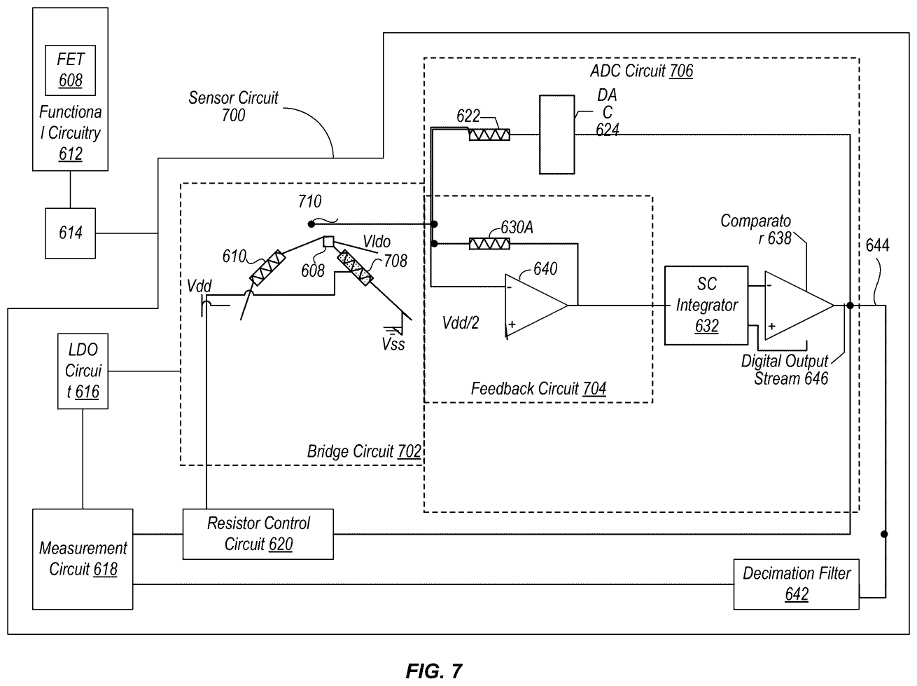

Turning now to temperature sensor circuits, FIGS. 6-7 depict various embodiments of circuits that implement first resistor stack 120 and second resistor stack 130 for temperature sensing. It should be understood that various transistor or transistor-based components described herein may be implemented as a FET (Field-Effect Transistor), MOSFET, a FinFET, or a GAAFET.

FIG. 6 depicts a block diagram of a sensor circuit 600, according to some embodiments. In the illustrated embodiment, sensor circuit 600 includes bridge circuit 602 (with FETs 608, resistors 610, and resistors 606), feedback circuit 604 (with resistors 630A, 630B and amplifier 640), and ADC (Analog-to-Digital Converter) circuit 626. Resistors 610 may be resistors formed by first resistor stacks 120 while resistors 606 may be resistors formed by second resistor stacks 130. In certain embodiments, resistors 610 have the positive temperature coefficient with a higher absolute value of first resistor stack while resistors 606 have the negative (or positive) temperature coefficient of resistors 606 with a lower absolute value. Accordingly, the resistance of resistors 610 has higher sensitivity to temperature changes than the resistance of resistors 606.

In the illustrated embodiment, bridge circuit 602 includes resistors 610 and resistors 606 coupled in a bridge configuration (e.g., Wheatstone bridge) between the source voltage (“Vdd”) and the ground voltage (“Vss”). In certain embodiments, bridge circuit 602 is coupled to feedback circuit 604. Feedback circuit 604 may be implemented to scale up the voltage of the signal from bridge circuit 602 to provide a stronger output signal(s) from amplifier 640. As shown in FIG. 6, feedback circuit 604 includes resistors 630A, 630B and amplifier 640 coupled to nodes 615A, 615B in bridge circuit 602. Nodes 615A, 615B are nodes coupled in series between resistors 610 and resistors 606 on either side of bridge circuit 602. Node 615A is coupled to resistor 630A and a first input (e.g., the negative input) of amplifier 640. Node 615B is coupled to resistor 630B and a second input (e.g., the positive input) of amplifier 640. Resistor 630A is also coupled to a first output (e.g., the positive output) of amplifier 640 while resistor 630B is also coupled to a second output (e.g., the negative output) of amplifier 640.

In certain embodiments, resistors (e.g., resistor 630A and resistor 630B) are feedback resistors with the same temperature coefficient as resistors 610. Thus, resistors 630A, 630B may be formed by first resistor stacks 120, described herein. In various embodiments, resistors 630A, 630B may have a higher resistance than resistors 610. As resistors 630A, 630B have the same temperature coefficient as resistors 610 but higher resistance, resistors 630A, 630B may provide gain for the signal from resistors 610 and bridge circuit 602. For example, the signal from bridge circuit 602 may be scaled up by a factor, k, determined by the resistance values of resistors 630A, 630B versus the resistance values of resistors 610.

Amplifier 640 may be, for example, an operational (e.g., transimpedance) differential amplifier that is implemented using a biased differential pair of inputs and outputs (e.g., the positive and negative inputs/outputs). Accordingly, amplifier 640 may provide bias control (and gain in combination with resistors 630A, 630B) for the signal from resistors 610 and bridge circuit 602. In some embodiments, amplifier 640 provides common mode voltage correction with the voltage correction being around Vdd/2 for the two outputs of bridge circuit 602 at nodes 615A, 615B.

In certain embodiments, output signal from the amplifier 640 is a signal that corresponds to the differential between the voltage across resistors 610 and the voltage across resistors 606. Because of the differences in temperature coefficients of resistors 610 and resistors 606, output signal of the amplifier 640 may be calibrated to indicate a temperature sensed (e.g., a temperature at or near the temperature sensor circuit).

In various embodiments, sensor circuit 600 also includes ADC circuit 626 (which includes feedback circuit 604 described above). ADC circuit 626 also includes switches 634, CMFB (Common Mode Feedback) amplifier 628, SC integrator 632, comparator 638, DACs (Digital-to-Analog Converter) 624, and resistors 622. The sensor circuit 600 may also include decimation filter 642, measurement circuit 618, resistor control circuit 620, and LDO (Low-Dropout) circuit 616. The functional circuitry 612 and the thermal system 614 may be external to the sensor circuit 600.

In one embodiment, the FETs 608 that are in the sensor circuit 600 and/or bridge circuit 602 may be similar and/or identical to the FET 608 that is in the functional circuitry 612. For example, resistance, size, materials, dimensions, etc., of the FETs 608 in the bridge circuit 602 may be similar and/or identical to the resistance, size, materials, dimensions, etc., of the FET 608 in the functional circuitry 612.

Switches 634 may be, for example, crossbar switches, that may switch the two inputs at predetermined times. Switching the inputs and the outputs using switches 634 may cancel any inherent offset in amplifier 640 caused by different electrical properties in the differential pair of the amplifier. CMFB 628 may be configured to sense the common mode voltage of the outputs of amplifier 640 and compare the outputs to a reference (e.g., Vldo/2). CMFB 628 may feed a signal back to adjust the common mode operating point of amplifier 640 based on the comparison of outputs to the reference.

SC integrator 632 may be, for example, a switched-capacitor integrator circuit configured to sample the outputs of amplifier 640 and then integrate the sampled values for a predetermined period of time. SC integrator 632 may generate a differentially encoded output based on the integrated sample values that is provided to comparator 638. In various embodiments, comparator 638 operates as an analog-to-digital converter circuit. Comparator 638 may change a logic value of its output based on a comparison of the two voltage levels input from SC integrator 632. Accordingly, comparator 638 may clamp its output at either the voltage level of the power supply (Vdd) or ground (Vss).

In various embodiments, as shown in FIG. 6, the output of comparator 638 is provided to DACs 624. DACs 624 may generate a global feedback current into or out of the inputs of amplifier 640, thus closing a global feedback loop around the sensor. The direction of the feedback current changes when the output of comparator 638 switches logic state, thereby causing SC integrator 632 to progress in the opposite direction. The feedback current passes through resistors 622. Resistors 622 may have the same temperature coefficient as resistors 610 and resistors 630A, 630B. Thus, resistors 622 may be formed from first resistor stack 120. The value and dynamic range of the feedback current may be determined by the value of resistors 622 (e.g., may be based on Vdd divided by the resistance of resistors 622). Accordingly, both bridge signal and feedback currents are ratiometric to Vdd, thereby providing closed loop cancellation of the absolute value of Vdd. In some embodiments, resistors 610 and 606 in the bridge can be current balanced with a single point calibration by making either pair a programmable DAC structure, for example, R2R DAC structures. Remaining gain errors from resistor mismatches can be removed through Dynamic Element Matching (DEM) and/or chopping modulation in some embodiments.

ADC circuit 626, shown in FIG. 6, may be a double-ended sigma-delta converter that generates a stream of digital bits whose value corresponds to a temperature detected by sensor circuit 600 based on resistors 610 and resistors 606 in bridge circuit 602. For example, bridge circuit 602 generates a voltage with a value that corresponds to the temperature based on the differential resistances between resistors 610 and resistors 606. Feedback circuit 604 provides gain and bias control for the voltage from bridge circuit 602. ADC circuit 626 then generates digital (bit) stream output 646 from the voltage output provided by feedback circuit 604. In various embodiments, digital stream output 646 generated by ADC circuit 626 has a ratio of the number of logical high values to the number of logical low values over a period of time that corresponds to the voltage from feedback circuit 604. Thus, the digital bit stream corresponds to the temperature represented by the differential voltages across resistors 610 and resistors 606.

In some embodiments, digital stream output 646 passes through decimation filter 642 after comparator 638. Decimation filter 642 may down sample the stream of bits in digital stream output 646. For example, decimation filter 642 may drop every nth bit by implementing a counter or other sequential logic circuit to track the bits being received by comparator 638. The output of decimation filter 642 may be provided as filtered digital stream output 644. The down sampling by decimation filter 642 may help in removing noise from digital stream output 646 that can be generated as the output of SC integrator 632 passes through the threshold of comparator 638, potentially causing the output of the comparator to quickly toggle between logic values.

In various embodiments, filtered digital stream output 644 is provided to measurement circuit 618. Measurement circuit 618 may include any logic circuit or other circuit that converts filtered digital stream output 644 to a temperature and/or a resistance as discussed in more detail below. For example, measurement circuit 618 may be a polynomial solver or other mathematical solver capable of converting a digital stream into a temperature. In various embodiments, measurement circuit 618 converts filtered digital stream output 644 to temperature based on a calibration determined for sensor circuit 600.

In one embodiment, the measurement circuit 618 may operate as a controller, a control circuit, etc., to control operations/functions of one or more parts of the sensor circuit 600. For example, the measurement circuit 618 may control operation of the FETs 608 (that are in the sensor circuit 600 and/or bridge circuit 602) by causing different voltages to be applied to the gate of the FETs 608. In another example, the measurement circuit 618 may control operation of the LDO circuit 616 (e.g., may instruct the LDO circuit 616 to provide different voltages). In a further example, the measurement circuit 618 may control operation of the of the resistor control circuit 620 (e.g., may instruct the resistor control circuit 620 to adjust/change the resistances of the resistors 606). In one embodiment, the measurement circuit 618 may control operation of the thermal system 614 (e.g., may instruct the thermal system 614 to heat/cool the FETs 608 in the sensor circuit and/or in the functional circuit 612 to a certain temperature). Although the measurement circuit 618 is illustrated as part of the sensor circuit 600, the measurement circuit 618 may be external or separate from the sensor circuit 600 in other embodiments.

In one embodiment, the sensor circuit 600 (e.g., measurement circuit 618) may determine a set of resistances (e.g., one or more resistances) of the portions of the functional circuitry 612. For example, the sensor circuit 600 may determine resistances for the FETs 608 (of the sensor circuit 600 and/or the bridge circuit 602) while the FETs 608 are in an on state (e.g., while the FETs 608 allows current flow through the FETs 608). The resistance of a FET 608 while the FET 608 is on may be referred to as an on resistance or R_on. The sensor circuit 600 may determine resistances for the FETs 608 at different voltages and/or at different temperatures. For example, FETs 608 may be at a first temperature. The LDO circuit 616 may provide multiple voltages to the functional circuitry 612 and/or FETs 608. The voltage that is provided by the LDO circuit 616 to the FETs 608 may be referred to as Vldo. The sensor circuit 600 may determine a resistance for a FET 608 at each of the multiple voltages, while the FET 608 is at the first temperature. A thermal system 614 may heat and/or cool FETs 608 to a second temperature. The sensor circuit 600 may determine a resistance for a FET 608 at each of the multiple voltages, while the FET 608 is at the second temperature. This process may be repeated for a range of temperatures and/or a range of voltages to measure/determine the resistance of the FETs 608 at different combinations of voltages and temperatures, as discussed in more detail below.

In one embodiment, the sensor circuit 600 (e.g., measurement circuit 618) may determine the resistance for the FETs 608 (of the sensor circuit 600 and/or the bridge circuit 602) at a certain temperature and at a certain voltage by balancing the bridge circuit 602. The FETs 608 may be heated/cooled to the certain or desired temperature by the thermal system 614. The LDO circuit 616 may provide the certain/desired voltage to the FETs 608 of the bridge circuit 602. The measurement circuit 618 may turn on the FETs 608 and may set, configure, adjust, etc., the FETs 608 such that the FETs 608 provide little or no resistance to current flowing through the FETs 608. For example, a FET 608 may generally have less resistance, the higher the voltage applied to a gate of the FET 608. The measurement circuit 618 may apply a higher or maximum voltage to the gates of the FETs 608 to reduce the resistance of the FETs 608 to the lowest resistance. Because the FETs 608 are configured to provide the least resistance (e.g., by providing the highest allowed voltage to the gate of the FETs 608 to turn on the FETs 608) the resistance to the current flowing through the FETs 608 and the bridge circuit 602 may be caused mainly by resistors 610 and 606. This resistance may be referred to as R_sensor. The resistor control circuit 620 may adjust the resistance of the resistors 606 (e.g., configurable/adjustable resistors) balance (e.g., match) the resistance of the resistors 610 with the resistance of the resistors 606. By balancing/matching the resistance of the resistors 610 with the resistance of the resistors 606, sensor circuit 600 may be able to determine/measure the resistance R_sensor.

In one embodiment, the resistor control circuit 620 may be a state machine or other logic that may adjust the resistance of the resistors 606 until the bridge circuit 602 is balanced. For example, the resistors 606 may be R2R DAC structures, as discussed above. The resistor control circuit 620 may provide different digital codes (e.g., different bits, bit patterns, etc.) to the R2R DAC structures to adjust, modify, the resistance of the R2R DAC structures.

After determining the resistance R_sensor, the measurement circuit 618 may turn on the FETs 608 (in bridge circuit 602) and may set, configure, adjust, etc., the FETs 608 such that the FETs 608 provide more or the most resistance to current flowing through the FETs 608. As discussed above, a FET 608 may generally have less resistance the higher the voltage applied to a gate of the FET 608. The measurement circuit 618 may apply a lower or the lowest voltage to the gates of the FETs 608 to increase the resistance of the FETs 608 to the highest resistance. Because the FETs 608 are configured to provide the highest resistance (e.g., by providing the lowest allowed voltage to the gates of the FETs 608 to turn on the FETs 608) the resistance to the current flowing through the FETs 608 and the bridge circuit 602 may be caused by both the resistors 610 and 606, and the FETs 608 themselves. This total resistance may be referred to as R_sensor+R_on, wherein R_on is the resistance of the FETs 608.

In one embodiment, the resistor control circuit 620 may adjust the resistance of the resistors 606 (e.g., configurable/adjustable resistors) balance (e.g., match) the resistance of the resistors 610 with the resistance of the resistors 606. By balancing/matching the resistance of the resistors 610 with the resistance of the resistors 606, sensor circuit 600 may be able to determine/measure the total resistance R_sensor+R_on. By subtracting the resistance of the resistors 610 and 606 (R_sensor) from the total resistance (R_sensor+R_on), the measurement circuit 618 may be able to determine the resistance of one or more of the FETs 608 (R_on), at the certain voltage and at the certain temperature.

In another embodiment, the measurement circuit 618 may be able to determine the total resistance R_sensor+R_on without balancing (e.g., matching) the resistance of the resistors 610 with the resistance of the resistors 606. For example, based on the imbalance between the resistance of the resistors 610 and the resistance of the resistors 606, the resistor control circuit 620 may be able to determine the total resistance R_sensor+R_on.

In one embodiment, the sensor circuit 600 may use different combinations of voltages and temperatures to determine the resistance of the FETs 608 (in bridge circuit 602) at different voltages and different temperatures. For example, the measurement circuit 618 may configure the FETs 608 to provide more or less resistance by applying different voltage to the gates of the FETs 608. The thermal system 614 may heat or cool the functional circuitry 612 and/or the FETs 608 to a set of temperatures. For each temperature (in the set of temperatures), the LDO circuit 616 may generate different voltages and provide the different voltages to the FETs 608. The sensor circuit 600 may measure the temperature of sensor circuit 600 and/or the functional circuitry 612 and the resistance of the FETs 608 for the specific temperature and the specific voltage. The measurement circuit 618 may record, store, etc., the resistances that are measured for different combinations of temperatures and voltages to generate a table, such as Table 1 below.

TABLE 1

| Ron | V1 | V2 | V3 | . . . | Vn |
|---|---|---|---|---|---|
| T1 | R_1-1 | R_1-2 | R_1-3 | . . . | R_1-n |
| T2 | R_2-1 | R_2-2 | R_2-3 | . . . | R_2-n |
| T3 | R_3-1 | R_3-2 | R_3-3 | . . . | R_3-n |
| . . . | . . . | . . . | . . . | . . . | . . . |
| Tn | R_n-1 | R_n-2 | R_n-3 | . . . | R_n-n |

Table 1 illustrates how different resistances of the FETs 608 (e.g., different R_ons) are correlated, mapped, associated, etc., with different temperatures and voltages. For example, the resistance R_1-1 is the resistance of the FET 608 (e.g., R_on) when a FET 608 is at the temperature T1 and a voltage V1 is provided to the FET 608 by the LDO circuit 616. In another example, the resistance R_3-n is the resistance (e.g., R_on) of the FET 608 when the FET 608 is at the temperature T3 and a voltage Vn is provided to the FET 608 by the LDO circuit 616.

In one embodiment, the sensor circuit 600 may use Vdd when determining/measuring the temperature of the sensor circuit 600 and/or of the functional circuitry 612. The sensor circuit 600 may also use Vldo when determining/measuring the resistances of the FETs 608 of the sensor circuit 600 (e.g., of the bridge circuit 602).

In one embodiment, the temperature values and/or resistance values may be used to determine whether functional circuitry 612 is operating within limits or parameters. For example, the temperature values may be used to determine whether the functional circuitry 612 exceeds a maximum temperature at a particular voltage. In another example, the resistance values may be used to determine whether the resistance of the functional circuitry 612 is below a threshold resistance. In another example, the temperature values and/or resistance values may be used to increase and/or optimize the performance of the functional circuitry 612. For example, the measured temperature and/or resistance values may indicate that the functional circuitry 612 is capable of using higher voltages (e.g., operating at higher frequencies) while using less power (when compared to other functional circuitry in other devices) because the functional circuitry 612 has less resistance at higher temperatures and/or voltages. This may allow a device (e.g., a computing device, an electronic device, etc.) that includes the functional circuitry 612 to operate the functional circuitry 612 more efficiently.

While ADC circuit 626, shown in FIG. 6, is a double-ended sigma-delta converter, various embodiments of single-ended sigma-delta converters may be contemplated. Single-ended sigma-delta converters may be implemented with single-ended bridges (e.g., half of bridge circuit 602 with one resistor 610 and one resistor 606 in series between Vdd and Vss). A single-ended sensor circuit (with a single-ended sigma-delta converter circuit, a single-ended bridge circuit, and a single-ended feedback circuit) may be implemented in embodiments where reduced power consumption and reduced area consumption are desired and less accuracy in temperature sensitivity is allowable.

FIG. 7 depicts a block diagram of a single-ended sensor circuit, according to some embodiments. In the illustrated embodiment, single-ended sensor circuit 700 includes single-ended bridge circuit 702, single-ended feedback circuit 704, and single-ended ADC circuit 706. In single-ended sensor circuit 700, bridge circuit 702 includes a FET 608, a single resistor 610 and a single resistor 708 coupled in series between Vdd and Vss. Output of bridge circuit 702 is provided through node 710 which is coupled between resistor 630A in feedback circuit 704 and resistor 622 in ADC circuit 706. Amplifier 640 receives the voltage output of bridge circuit 702 at a first input (e.g., the negative input) along with Vdd/2 at a second input (e.g., the positive input). Amplifier generates an output signal based on a comparison between the voltage output of bridge circuit 702 (plus feedback provided from resistor 630A, DAC 624, and resistor 622) and Vdd/2. Subsequently, SC integrator 632 and comparator 638 in ADC circuit 706 operate similarly to the embodiment of ADC circuit 706, shown in FIG. 6, to provide digital stream output 646. As described above, digital stream output 646 may be filtered through decimation filter 642 to generate filtered digital stream output 644, which may be converted to a temperature and/or one or more resistances by the measurement circuit 618.

In one embodiment, the FET 608 that is in the sensor circuit 700 and/or bridge circuit 702 may be similar and/or identical to the FET 608 that is in the functional circuitry 612. For example, resistance, size, materials, dimensions, etc., of the FET 608 in the bridge circuit 702 may be similar and/or identical to the resistance, size, materials, dimensions, etc., of the FET 608 in the functional circuitry 612.

As discussed above, the measurement circuit 618 may operate as a controller, a control circuit, etc., to control operations/functions of one or more parts of the sensor circuit 600. Although the measurement circuit 618 is illustrated as part of the sensor circuit 600, the measurement circuit 618 may be external or separate from the sensor circuit 600 in other embodiments.

In one embodiment, the sensor circuit 600 (e.g., measurement circuit 618) may determine a set of resistances (e.g., one or more resistances) of the portions of the functional circuitry 612 (e.g., for the FETs 608 while the FETs 608 are in an on state). The sensor circuit 600 may determine resistances for the FET 608 at different voltages and/or at different temperatures. For example, the thermal system 614 may be used to heat/cool sensor circuit 700 and/or FETs 608 to different temperatures. For each temperature, the LDO circuit 616 may provide multiple voltages (e.g., Vldo) to the FETs 608. The sensor circuit 600 may determine a resistance for the FETs 608 at each of the multiple voltages for a particular temperature. This process may be repeated for a range of temperatures and/or a range of voltages to measure/determine the resistance of the FETs 608 at different combinations of voltages and temperatures.

As discussed above, when measuring the resistance, the measurement circuit 618 may turn on the FETs 608 (of bridge circuit 702 and/or sensor circuit 700) and may set, configure, adjust, etc., the FETs 608 such that the FETs 608 provide little or no resistance to current flowing through the FETs 608 (e.g., configure the FETs 608 with low resistance) to measure/determine R_sensor. The measurement circuit 618 may also set, configure, adjust, etc., the FETs 608 such that the FETs 608 provides more or the most resistance to current flowing through the FETs 608 (e.g., configure the FETs 608 with high resistance) to measure/determine the total resistance R_sensor+R_on. The resistor control circuit 620 may adjust the resistance of the resistors 606 (e.g., configurable/adjustable resistors) balance (e.g., match) the resistance of the resistors 610 with the resistance of the resistors 606, when the measurement circuit 618 measures/determining the resistors. The measurement circuit 618 may record, store, etc., the resistances that are measured for different combinations of temperatures and voltages to generate Table 1 above. As discussed earlier, Table 1 illustrates how different resistances of the FETs 608 (e.g., different R_ons) are correlated, mapped, associated, etc., with different temperatures and voltages.

In one embodiment, the sensor circuit 700 may use Vdd when determining/measuring the temperature of the sensor circuit 600 and/or of the functional circuitry 612. The sensor circuit 600 may also use Vldo when determining/measuring the resistances of the FETs 608 of the sensor circuit 600 (e.g., of the bridge circuit 602).

In one embodiment, the temperature values and/or resistance values may be used to determine whether or not functional circuitry 612 is operating within limits or parameters. In another embodiment, the temperature values and/or resistance values may be used to increase and/or optimize the performance of the functional circuitry 612.

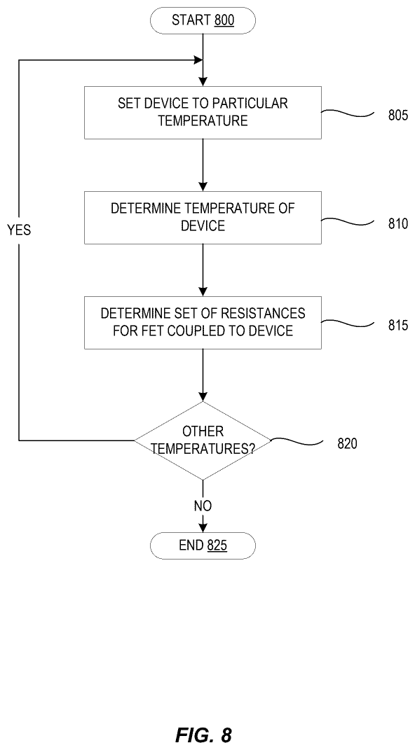

FIG. 8 illustrates a flow diagram depicting a method for measuring temperatures and/or resistances, in accordance with one or more embodiments of the present disclosure. The method, which may be performed by one or more of sensor circuit 600 illustrated in FIG. 6, sensor circuit 700 illustrated in FIG. 7, and/or various components of sensor circuits 600 and 700, starts at the block 800.

The method includes setting a device (e.g., a sensor circuit) to a particular temperature (e.g., a known temperature, a desired temperature, etc.) at block 805. The method also includes determining the temperature of the device at block 810. As discussed above, the integrated circuit device may be set to a particular (e.g. known or desired) temperature. Block 805 may be performed to verify that the integrated circuit device is at the particular (e.g., known or desired) temperature.

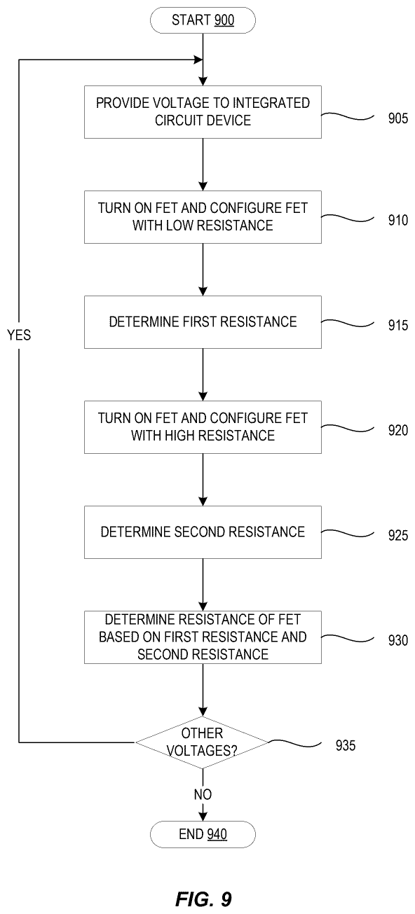

At block 815, a set of resistances for a FET (that is coupled to the device and/or part of the device) are determined. For example, the method may include some or all of the steps illustrated in FIG. 9 to determine the set of resistances, as discussed in more detail below. At block 820, the method includes determining whether there are additional temperatures for the device. For example, there may be a list of temperatures for the device that should be used to determine resistance at each of the temperatures in the list and generate values for a table similar to that shown above in Table 1. If there are additional temperatures, the method may proceed back to block 805. If there are no additional temperatures, the method ends at block 825.

FIG. 9 illustrates a flow diagram depicting a method for measuring temperatures and/or resistances, in accordance with one or more embodiments of the present disclosure. The method, which may be performed by one or more of sensor circuit 600 illustrated in FIG. 6, sensor circuit 700 illustrated in FIG. 7, and/or various components of sensor circuits 600 and 700, starts at the block 900.

The method includes providing a voltage to the integrated circuit device (e.g., a sensor circuit) at block 905. For example, LDO circuit 616 may be used to provide a particular voltage to the integrated circuit device. The voltage may be provided directly to the integrated circuit device and/or directly to one or more FETs of the integrated circuit device.

At block 910, the one or more FETs of the integrated circuit device are turned on and configured with a low or the lowest resistance. For example, a high or maximum voltage may be applied to the gates of the FETs to set the one or more FETs to a low resistance. At block 915, a first resistance may be determined/measured. For example, the resistance R_sensor may be determined.

At block 920 the FETs may be turned on (and/or may remain on). The FETs may be configured with a high or the highest resistance. For example, a low or minimum voltage may be applied to the gates of the FETs. At block 925, a second resistance may be determined/measured. For example, a total resistance R_sensor+R_on may be determined. At block 930, the resistances of the FETs are determined based on the first resistance and the second resistance. For example, the difference between the second resistance and the first resistance may be determined.

At block 935, the method determines whether there are other voltages that should be provided to the integrated circuit device. For example, there may be a list of voltages that should be used for measuring resistances so that a table similar to the Table 1 above may be generated. The method may include determining whether there are any other voltages on the list that have not been used. If there are other voltages that should be used, the method may proceed back to block 905. If there are no other voltages that should be used, the method ends at block 940.

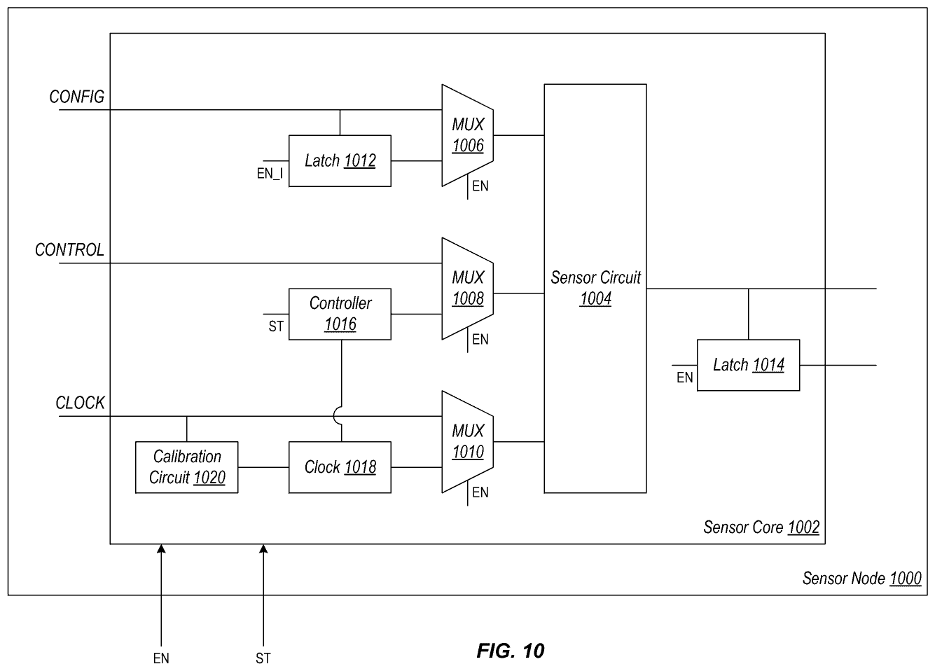

FIG. 10 is a block diagram of a sensor node 1000. The sensor node 1000 may be a circuit that is used to detect the temperature of a portion of a device (e.g., a processing unit, functional circuitry, etc.). The sensor node 1000 includes a sensor core 1002 and/or other circuitry, connections, wires, etc., that may be used in conjunction with the sensor core 1002. The sensor core 1002 includes a sensor circuit 1004, MUX 1006, MUX 1008, MUX 1010, latch 1012, latch 1014, controller 1016, clock 1018, and calibration circuit 1020, which are discussed in more detail below.

The controller 1016 may be logic (e.g., a state machine) and/or a circuit that is used to control, manage, direct, etc., the operation of the sensor circuit 1004. The clock 1018 may be a circuit that may generate an internal timing/clock signal when the CLOCK signal is not available. The sensor circuit 1004 may be any circuit that may be used to detect/measure/sense temperatures. Example of sensor circuit 1004 may include temperature sensor circuit 600 (illustrated in FIG. 6), temperature sensor circuit 700 (illustrated in FIG. 7), and any other circuit that is appropriate for measuring temperatures. Latches 1012 and 1014 may be circuits that may store data, information, bits, etc. For example, latches 1012 and 1014 may be memory devices or may operate as a memory.

The sensor node 1000 also includes two inputs (e.g., pins, connections, lines, etc.). The first input receives an enable (EN) signal and the second input receives a start (ST) signal. The EN and ST signals may be provided by another device/circuit that is separate from the sensor node 1000 and/or the sensor core 1002. The EN and ST signals are provided to the MUXs 1006, 1006, 1010, and latch 1014. The EN signal is inverted to generate the signal EN_I and the (inverted) signal EN_I is provided to the latch 1012. The sensor core 1002 may receive multiple signals from the sensor node 1000 (or from a device external to the sensor node 1000). For example, the sensor node 1000 may receive a CONFIG signal (which may be used to configure the sensor circuit 1004), a CONTROL signal (which may be used to control/operate the sensor circuit 1004), and a CLOCK signal (which may be used to provide timing or a clock for the sensor circuit 1004).

In one embodiment, the sensor core 1002 may operate in (or may be located in and/or coupled to) a different power domain than the sensor node 1000. A power domain may refer to a group, set, collection, etc., of devices and/or circuits that share a supply voltage. The sensor core 1002 may operate in or may be coupled to a first power domain and the sensor node 1000 may operate in or may be coupled to a second, separate power domain.

In one embodiment, operating on a different power domain than the sensor node 1000 may allow the sensor core 1002 (e.g., sensor circuit 1004) to perform a more accurate determining of the temperature of the sensor node 1000. For example, operating the sensor core 1002 and the sensor node 1000 on different power domains may allow for a more accurate calibration of the sensor core 1002 (e.g., of the sensor circuit 1004). The more accurate calibration of the sensor core 1002 may allow the sensor core 1002 to perform more accurate measurements of the temperature of the sensor core 1002 and/or the sensor node 1000.

In one embodiment, the second power domain for the sensor node 1000 may be turned off, power down, etc. This may allow the sensor node 1000 and/or the device (e.g., processing unit, functional circuitry, etc.) that is being measured by the sensor node 1000 to cool down to a desired/known temperature, such as room temperature, an ambient temperature, 25 degrees Celsius, etc. The first power domain for the sensor core 1002 may remain on, because the sensor core 1002 needs power to perform temperature measurements. Because the sensor node 1000 is off (e.g., is not operating), the temperature that is detected by the sensor core 1002 (e.g., by the sensor circuit 1004) can be calibrated or set to the desired/known temperature. This may allow for more accurate temperature measurements once the other power domains are turned on.

In one embodiment, the sensor core 1002 may be initialized when both the first power domain and the second power domain are on. The EN signal is set to logical low (e.g., sent to off or 0) and the ST signal is set to logical low (e.g., set to on or 1). When the ENG signal is set to logical low, the MUXs 1006, 1008, and 1010 will provide the signal from their respective top/upper inputs to the sensor circuit 1004. For example, when the EN signal is set to logical low, MUX 1006 will provide the CONFIG signal to the sensor circuit 1004, MUX 1008 will provide the CONTROL signal to the sensor circuit 1004, and MUX 1006 may provide the CLOCK signal to the sensor circuit 1004. The CLOCK signal is also provided to the calibration circuit 1020.

As discussed above, the latch 1012 receives EN_I (which is set to logical high when the EN signal is set to logical low) and the latch 1012 may store the configuration data (e.g., information, parameters, bits, etc.) that is provided in the CONFIG signal. The stored configuration data may be used to configure the sensor circuit 1004 when the second power domain (for the sensor node 1000) is turned off. The calibration circuit 1020 may use the CLOCK signal to calibrate, configure., etc., the clock 1018. For example, the calibration circuit 1020 may configure the clock 1018 to operate at the same frequency as the CLOCK signal. This may allow the sensor circuit 1004 to operate at the same frequency as the CLOCK signals when the second power domain (for the sensor node 1000) is turned/powered off.

When the calibration of the sensor core 1002 starts (e.g., when the calibration process starts), the EN signal is set to logical high and the ST signal is set to logical low. The second power domain (for sensor node 1000) is then turned/powered off. When the EN signal is set to logical high, the MUXs 1006, 1008, and 1010 may provide signals from their respective bottom/lower inputs to the sensor circuit 1004. For example, the MUX 1008 may provide the configuration data that is stored in the latch 1012 to the sensor circuit 1004 to configure the sensor circuit. In another example, signals from the controller 1016 may be provided to the sensor circuit 1004 to control operation of the sensor circuit 1004. In a further example, an internal timing/clock signal from the clock 1018 is provided to the controller 1016 and to the sensor circuit 1004.

In one embodiment, the controller 1016 may wait for a period of time after the second power domain is turned off for the device or portion of the device to cool to a desired, particular, and/or known temperature (e.g., ambient/room temperature). After the device and/or portion of the device has cooled to the particular temperature, the ST signal may be set to a logical high. The controller 1016 may start operation of the sensor circuit 1004 to detect the temperature of the device and/or portion of the device. Because the device and/or portion of the device is at a known temperature (e.g., ambient/room temperature, a temperature that is set by a thermal device/system, etc.), the temperature detected by the sensor circuit 1004 may be calibrated to the known temperature (e.g., the temperature detected by the sensor circuit 1004 may be set as equivalent to the known temperature). That temperature detected by the sensor circuit may be stored in the latch 1014.

After the sensor core 1002 and/or sensor circuit 1004 has been calibrated, the second power domain may be turned back on, the EN signal may be set to a logical low, and the ST signal may be set to a logical low. The sensor node 1000 and/or sensor core 1002 may resume normal operations using the CONFIG, CONTROL, and CLOCK signals.

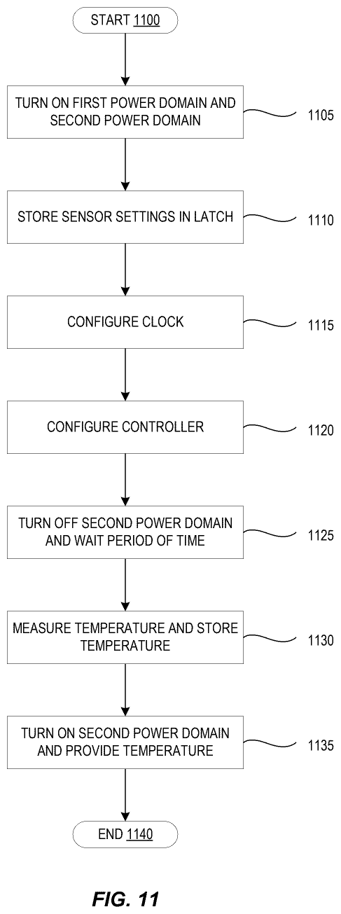

FIG. 11 illustrates a flow diagram depicting an embodiment of a method for calibrating a sensor, in accordance with one or more embodiments of the present disclosure. The method, which may be performed by one or more of sensor core 1002 and sensor node 1000 illustrated in FIG. 10, starts at the block 1100.

The method includes turning on a first power domain and a second power domain at block 1105. The sensor core 1002 may be part of the first power domain and the sensor node 1000 may be part of the second power domain, as discussed above.

Sensor settings are stored in a latch (or a memory) at block 1110. For example, a control signal may provide sensor settings that are stored in the latch. A clock circuit may be configured at block 1115. For example, a CLOCK signal may be used to configure the frequency of the of the clock circuit.

A controller is optionally configured at block 1120. For example, the controller may initialized, turned on, etc. The controller may be used to control operation of a sensor circuit of the sensor core 1002.

At block 1125, the second power domain is turned off and the method may include waiting for a period of time. For example, the method may include waiting for a device to reach a known or desired temperature. At block 1130, the temperature of the device is measured and stored in a latch or memory.

At block 1135, the second power domain is turned on and the temperature of the device may be provided to the device and/or another controller (e.g., am MCC). The method ends at lock 1140.

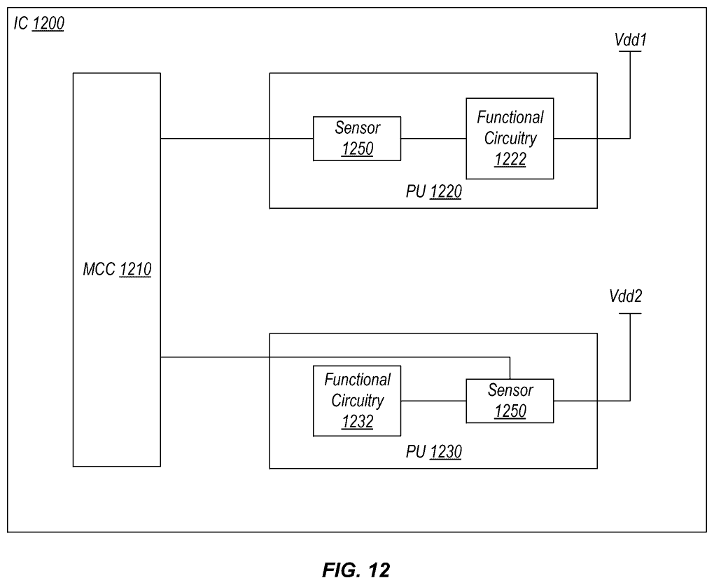

FIG. 12 depicts a block diagram of an embodiment of an integrated circuit (IC). In the illustrated embodiment shown, IC 1200 includes metrology control circuitry (MCC) 1210 and two functional circuit blocks, processing unit (PU) 1220, and PU 1230. In various embodiments, other functional circuit blocks may be included, including additional instances of PU 1220 or PU 1230. PU 1220 and PU 1230 are thus shown here as exemplary functional circuit blocks, but are not intended to limit the scope of this disclosure. Each of PU 1220 and 1230 may be a general purpose processor core, a central processing unit (CPU), a graphics processing unit (GPU), a digital signal processing unit, or virtually any other kind of functional unit/circuitry configured to perform a processing function. The scope of this disclosure may apply to any of these types of functional circuit blocks, as well as others not explicitly mentioned herein. The number of functional circuit blocks shown here is by way of example as well, as the disclosure is not limited to any particular number.

In certain embodiments, PU 1220 may be a general purpose processor core configured to execute the instructions of an instruction set and perform general purpose processing operations. Functional circuitry 1222 of PU 1220 may thus include various types of circuitry such as execution units of various types, register files, schedulers, instruction fetch units, various levels of cache memory, and other circuitry that may be implemented in a processor core. In certain embodiments, functional circuitry 1222 in PU 1220 is coupled to receive first supply voltage Vdd1. In other embodiments, PU 1220 may be a GPU that may implement various types of graphics processing circuitry. This may include graphics processing cores, various types of memory and registers, and so on.

In certain embodiments, PU 1230 may be a general purpose processor core configured to execute the instructions of an instruction set and perform general purpose processing operations (e.g., functional circuitry 1222 may include execution units of various types, register files, schedulers, instruction fetch units, various levels of cache memory, and other circuitry that may be implemented in a processor core). In certain embodiments, functional circuitry 1232 in PU 1230 is coupled to receive second supply voltage Vdd2. In other embodiments, PU 1230 may be a GPU that may implement various types of graphics processing circuitry. This may include graphics processing cores, various types of memory and registers, and so on.

In certain embodiments, both PU 1220 and PU 1230 include a sensor 1250. The particular number of sensors 1250 (e.g., one sensor for PU 1220 and one sensor for PU 1230) illustrate in FIG. 12 is for example only, and in actual embodiments may be greater, lesser, or equal. Sensors 1250 may be configured for sensing one or more operating properties of PU 1220 or PU 1230 (e.g., performance metrics or parameters of the processing units). In certain embodiments, sensors 1250 are configured to sense one or more of operating voltages (e.g., local operating voltages), operating temperature values (e.g., operating temperature values for PU 1220 and/or PU 1230), and/or resistances (e.g., resistances of functional circuitry 1222 and/or functional circuitry 1232). For example, the sensors 1250 may be configured to sense the resistance of one or more FETs (e.g., MOSFETS) that are in the functional circuitry 1222 and/or functional circuitry 1232. For example, the sensors 1250 may include FETs that are similar or identical to the FETs that are in the functional circuit 1222 (e.g., the FETs in the sensors 1250 may have similar/identical sizes, characteristics, materials, etc.). The sensors 1250 may be configured to sense the resistance of the one or more FETs in the sensors 1250 at different voltage levels and/or at different temperatures, as discussed in more detail below.

Sensors 1250 may implement, for example, any of the sensor circuits described herein. For instance, sensor 1250 may implement temperature sensor circuit 600, shown in FIG. 6, and/or temperature sensor circuit 700, shown in FIG. 7. The sensed voltage, temperature values, and/or resistances may in turn be used to determine whether or not circuitry implemented therein (e.g., functional circuitry 1222 or functional circuitry 1232) is operating within limits, must be restricted to lower performance operation, and/or is capable of higher performance. In some embodiments, sensors 1250 are configured to sense other local operating values such as, but not limited to, current.

As illustrated in FIG. 12, PU 1220 is coupled to receive first supply voltage Vdd1. Vdd1 is provided to the functional circuit 1222. In one embodiment, Vdd1 is also provided to the sensor 1250 via the functional circuit 1222 (e.g., through the functional circuit 1222). Also as illustrated in FIG. 12, PU 1230 is coupled to receive second supply voltage Vdd2. Vdd1 is provided to the sensor 1250. In another embodiment, Vdd2 is also provided to the functional circuit 1232 via the sensor 1250 (e.g., through the sensor 1250).

In one embodiment, other voltages may be provided to the PU 1220 and/or the PU 1230. For example, a low-dropout (LDO) circuit (e.g., LDO circuit 616 illustrated in FIGS. 6 and 7) may provide different voltages to the PU 1220 and/or the PU 1230.

### Example Computer System

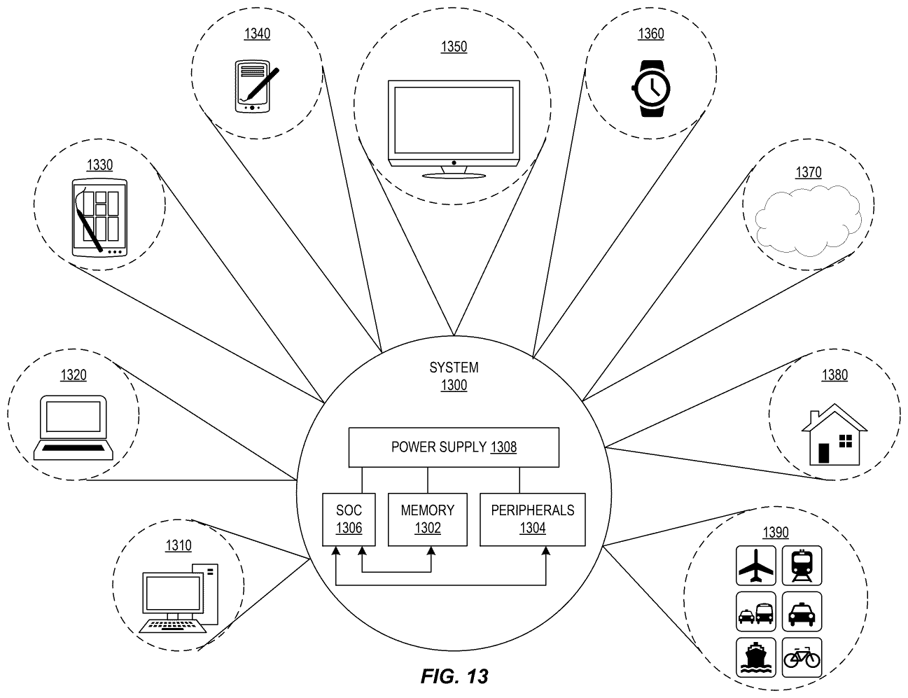

Turning next to FIG. 13, a block diagram of one embodiment of a system 1300 is shown that may incorporate and/or otherwise utilize the methods and mechanisms described herein. In the illustrated embodiment, the system 1300 includes at least one instance of a system on chip (SoC) 1306 which may include multiple types of processing units, such as a central processing unit (CPU), a graphics processing unit (GPU), or otherwise, a communication fabric, and interfaces to memories and input/output devices. In some embodiments, one or more processors in SoC 1306 includes multiple execution lanes and an instruction issue queue. In various embodiments, SoC 1306 is coupled to external memory 1302, peripherals 1304, and power supply 1308.

A power supply 1308 is also provided which supplies the supply voltages to SoC 1306 as well as one or more supply voltages to the memory 1302 and/or the peripherals 1304. In various embodiments, power supply 1308 represents a battery (e.g., a rechargeable battery in a smart phone, laptop or tablet computer, or other device). In some embodiments, more than one instance of SoC 1306 is included (and more than one external memory 1302 is included as well).

The memory 1302 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 1304 include any desired circuitry, depending on the type of system 1300. For example, in one embodiment, peripherals 1304 includes devices for various types of wireless communication, such as Wi-Fi, Bluetooth, cellular, global positioning system, etc. In some embodiments, the peripherals 1304 also include additional storage, including RAM storage, solid state storage, or disk storage. The peripherals 1304 include user interface devices such as a display screen, including touch display screens or multitouch display screens, keyboard or other input devices, microphones, speakers, etc.

As illustrated, system 1300 is shown to have application in a wide range of areas. For example, system 1300 may be utilized as part of the chips, circuitry, components, etc., of a desktop computer 1310, laptop computer 1320, tablet computer 1330, cellular or mobile phone 1340, or television 1350 (or set-top box coupled to a television). Also illustrated is a smartwatch and health monitoring device 1360. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 1300 may further be used as part of a cloud-based service(s) 1370. For example, the previously mentioned devices, and/or other devices, may access computing resources in the cloud (i.e., remotely located hardware and/or software resources). Still further, system 1300 may be utilized in one or more devices of a home 1380 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 13 is the application of system 1300 to various modes of transportation 1390. For example, system 1300 may be used in the control and/or entertainment systems of aircraft, trains, buses, cars for hire, private automobiles, waterborne vessels from private boats to cruise liners, scooters (for rent or owned), and so on. In various cases, system 1300 may be used to provide automated guidance (e.g., self-driving vehicles), general systems control, and otherwise. These any many other embodiments are possible and are contemplated. It is noted that the devices and applications illustrated in FIG. 13 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” or is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. A circuit comprising:
a first resistor stack, wherein the first resistor stack has a first temperature coefficient;
a second resistor stack coupled to the first resistor stack, wherein the second resistor stack has a second temperature coefficient different than the first temperature coefficient; and
a measurement circuit associated with the first resistor stack and the second resistor stack, the measurement circuit configured to:
determine a temperature based on a differential between a first voltage across the first resistor stack and a second voltage across the second resistor stack; and
determine a set of resistances of a field-effect transistor (FET) that is operatively coupled to the measurement circuit based on additional differentials between additional voltages across the first resistor stack and the second resistor stack.

2. The circuit of claim 1, wherein the second resistor stack comprises one or more adjustable resistors and wherein the circuit further comprises:
a resistor control circuit configured to adjust one or more resistances resistance of the one or more adjustable resistors.

3. The circuit of claim 1, wherein the measurement circuit is further configured to control operation of the FET.

4. The circuit of claim 1, wherein the first resistor stack and the second resistor stack are coupled in series between a voltage supply and a voltage ground.

5. The circuit of claim 4, wherein the voltage supply comprises a low-drop out (LDO) circuit.

6. The circuit of claim 1, wherein each resistance of the set of resistances is associated with a respective temperature and a respective voltage.

7. The circuit of claim 1, further comprising:
an amplifier having an input and an output, and wherein the input of the amplifier is coupled to a node between the first resistor stack and the second resistor stack.

8. The circuit of claim 7, further comprising:
a feedback resistor stack, the feedback resistor stack being coupled to the output of the amplifier and to the node between the first resistor stack and the second resistor stack, and wherein the feedback resistor stack has the first temperature coefficient.

9. The circuit of claim 8, wherein the amplifier is configured to output a signal with a voltage that corresponds to differentials between a resistance of the first feedback resistor stack and a resistance of the second resistor stack, the output signal being indicative of the temperature of an integrated circuit device.

10. The circuit of claim 8, the amplifier is configured to output a signal that corresponds to differentials between a resistance of the first feedback resistor stack and a resistance of the second resistor stack, the output signal being indicative of the set of resistances of the FET.

11. The circuit of claim 1, wherein the circuit operates within a first power domain and wherein the FET is included in a circuit that operates within a second power domain.

12. The circuit of claim 11, wherein the circuit is calibrated by turning off the second power domain and determining the temperature while the second power domain is off.

13. An apparatus, comprising:
a first resistor stack comprising one or more resistors;
a second resistor stack coupled to the first resistor stack, the second resistor stack comprising one or more resistors, wherein:
the first resistor stack has a first temperature coefficient and the second resistor stack has a second temperature coefficient, the first temperature coefficient having an absolute value higher than an absolute value of the second temperature coefficient; and
wherein differentials between a first voltage across the first resistor stack and a second voltage across the second resistor stack are indicative of a temperature of the apparatus and one or more resistances of a field-effect transistor (FET) that is coupled to the apparatus.

14. The apparatus of claim 13, wherein the second resistor stack comprises one or more adjustable resistors and wherein the apparatus further comprises:
a resistor control circuit configured to adjust one or more resistances resistance of the one or more adjustable resistors.

15. The apparatus of claim 13, wherein the first resistor stack and the second resistor stack are coupled in series between a voltage supply and a voltage ground.

16. The apparatus of claim 15, wherein the voltage supply comprises a low-drop out (LDO) circuit.

17. The apparatus of claim 13, wherein the second resistor stack comprises one or more adjustable resistors.

18. A method, comprising:
determining a temperature of an apparatus based on a differential between a first voltage across a first resistor stack of the apparatus and a second voltage across a second resistor stack of the apparatus, wherein the first resistor stack has a first temperature coefficient and the second resistor stack has a second temperature coefficient different than the first temperature coefficient; and
determining a set of resistances of a field-effect transistor (FET) that is coupled to the apparatus based on additional differentials between additional voltages across the first resistor stack and the second resistor stack.

19. The method of claim 18, wherein each resistance of the set of resistances is associated with a respective temperature and a respective voltage.

20. The method of claim 18, further comprising:
adjusting the temperature of the apparatus; and
determining a second temperature of an apparatus based on a second differential between a first voltage across a first resistor stack of the apparatus and a second voltage across a second resistor stack of the apparatus; and
determining a further set of resistances of a field-effect transistor (FET) that is coupled to the apparatus based on further differentials between further voltages across the first resistor stack and the second resistor stack.
